(19) United States
(12) Patent Application Publication
(10) Pub. No.: US 2003/0142742 A1
(43) Pub. Date: Jul. 31, 2003

(54) Modulation by combined multi-pulse per group with simultaneous phase and time shift keying and method of using the same

(75) Inventor: Clinton S. Hartmann, Dallas, TX (US)

Correspondence Address: HITT GAINES P.C., P.O. BOX 832570, RICHARDSON, TX, 75083, US

(73) Assignee: RF SAW Components, Incorporated, Dallas, TX (US)

(21) Appl. No.: 10/062,894

(22) Filed: Jan. 30, 2002

(51) Int. Cl. H03K 7/04

(52) U.S. Cl. 375/239

(57) ABSTRACT

The present invention in one embodiment provides for a propagated signal of (1) a time period divided into a group of time slots each having a unique phase/time position; and (2) multiple pulses distributed among the time slots encoding a data element by such unique phase/time position.

### TECHNICAL FIELD OF THE INVENTION

The present invention is directed, in general, to a propagated signal and, more specifically, to a propagated signal modulated by combining multi-pulse per group modulation with simultaneous phase and time shift modulation.

### BACKGROUND OF THE INVENTION

Electronic data transmission requires some form of signal modulation that encodes data onto an information bearing signal so that the signal can be propagated over a transmitting medium and demodulated to unambiguously recover the data originally encoded. Modulation can be viewed as the process by which digital data, voice, music, and other “intelligence” is added to radio waves produced by a transmitter so that the intelligence is in a form suitable for propagation. Modulation can also be viewed as the addition of information to an electronic or optical signal carrier in a manner that permits the encoded data to be reliably decoded. Modulation can be applied to direct current (mainly by turning it on and off), to alternating current, and to optical signals. One can even view blanket waving as a form of modulation used in smoke signal transmission (the carrier being a steady stream of smoke). Morse code, invented for telegraphy and still used in amateur radio, is a method of modulation that uses a binary (two-state) digital code similar to the code used by modern computers.

Modulation implies the occupancy of bandwidth, a precious resource the conservation of which is of increasing importance to all but most particularly to those in the data and information transmission business. Bandwidth conservation requirements has increased the pressure on users to make the most efficient use of bandwidth as technology permits. One method to increase bandwidth efficiency is to utilize transmission techniques that maximize the amount of data or information that is transmitted over a limited period of time. One way to increase the amount of data transmitted over a limited time period is to utilize those modulation methods that maximize encoded data transmitted over the allocated time period.

A number of methods are now being used to modulate electronic signals to transmit digital data. For most radio and telecommunication uses, the carrier being modulated is alternating current (AC) within a given range of frequencies. Some of the more common modulation methods include: amplitude modulation (AM), in which the amplitude of the carrier signal is varied over time; frequency modulation (FM), in which the frequency of the carrier signal is varied; and phase modulation (PM), where the phase of the carrier signal is varied over time. These are all classified as continuous wave modulation methods in order to distinguish them from the pulse code modulation (PCM) methods used to encode digital and analog information in a binary way. There are also more complex forms of modulation, such as phase shift keying (PSK) and quadrature amplitude modulation (QAM), as well as methods to modulate optical signals by applying an electromagnetic current that varies the intensity of a laser beam.

Depending on the intended use, all the foregoing methods of modulation permit a relatively reliable transmission of electronic data over a distance. However, as more and more bandwidth is being used because of a constantly increasing amount of data to be transmitted, there exists a need for even more efficient data transmission capability. As more information is digitized, even more pressure is exerted on transmission systems and bandwidth demand. Although improved equipment and technology is of some help in resolving the problems caused by an increased demand for bandwidth, other solutions are also required.

One way to partially resolve the problem of limited bandwidth is to encode more data on the carrier. If the amount of data transferred over a limited period of time is increased, the infrastructure and equipment required to support such infrastructure can be significantly reduced.

Thus, what is required in the art are new and novel methods to modulate electronic signals that increase the amount of digital data that can be transferred and the rate at which such transfer can occur.

### SUMMARY OF THE INVENTION

To address the above-discussed deficiencies of the prior art, the present invention for a propagated signal of (1) a time period divided into a group of time slots each having a unique phase/time position; and (2) multiple pulses distributed among the time slots encoding a data element by such unique phase/time position.

The present invention therefore introduces the broad concept of a propagated signal that has data encoding by more than one pulse in a group of slots having unique phase/time positions in a time period. This new and novel method of encoding a signal permits a dramatic increase in the amount of data a propagated signal can carry over a specific period of time as compared to that which could be carried using prior art encoding methods.

In one embodiment, the propagated signal has a data element that is ascertainable by mapping. In another embodiment of the invention, the propagated signal has time slots in the group that are adjacent while in another embodiment the time slots are not adjacent. In still another embodiment of the invention, the propagated signal has time slots that have a non-uniform spacing.

In a particularly beneficial embodiment of the invention the propagated signal has a data element that is at least fifteen bits long. As will be understood by those of ordinary skill in the pertinent art, a data element that is fifteen bits long permits a large number of unique codes to be encoded thereon.

In yet still another embodiment of the invention, the data element is selected from the group consisting of a header; an error detection message; and a data message. As will be understood by those of ordinary skill in the pertinent art, a propagated signal will most likely contain a number of data elements that, when combined, make up a discrete body of information. Such a propagated signal may well contain different types of data elements so that the discrete body of information will have some combination of header data, data message, synchronization elements, and error detection elements.

One embodiment of the present invention provides for a propagated signal that has a plurality of time periods. Another aspect of this embodiment provides for a propagated signal where the groups have differing numbers of multiple pulses. In yet still another aspect of this embodiment, the number of time slots vary in the time periods provided.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

For a more complete understanding of the present invention, reference is now made to the following descriptions taken in conjunction with the accompanying drawings, in which:

FIGS. 1A-1D illustrate graphs of the pulse positions of a conventional prior art digital pulse position modulation (PPM) method where data is encoded by a pulse located in one of four pulse positions;

FIG. 2 illustrates the group of four slots separately illustrated in FIGS. 1A-1D, showing the correct conventional PPM pulse position for each pulse;

FIG. 3 illustrates an example of waveforms of multiple pulses with a large skirt overlap between adjacent pulse positions;

FIG. 4 illustrates a graph showing the limited detection margin between adjacent slot positions where a signal has strongly overlapping pulses;

FIGS. 5A-5B illustrate the real and imaginary parts of allowable pulses for the case of +90° phase being added between each adjacent pulse;

FIG. 6 illustrates a graph showing the wave forms for an embodiment of the present invention using a 78.5° phase difference between adjacent allowed states; and

FIG. 7 illustrates an example of an application of a minimum spacing rule that allows multiple pulses per group along with simultaneous phase and time shift modulation.

### DETAILED DESCRIPTION

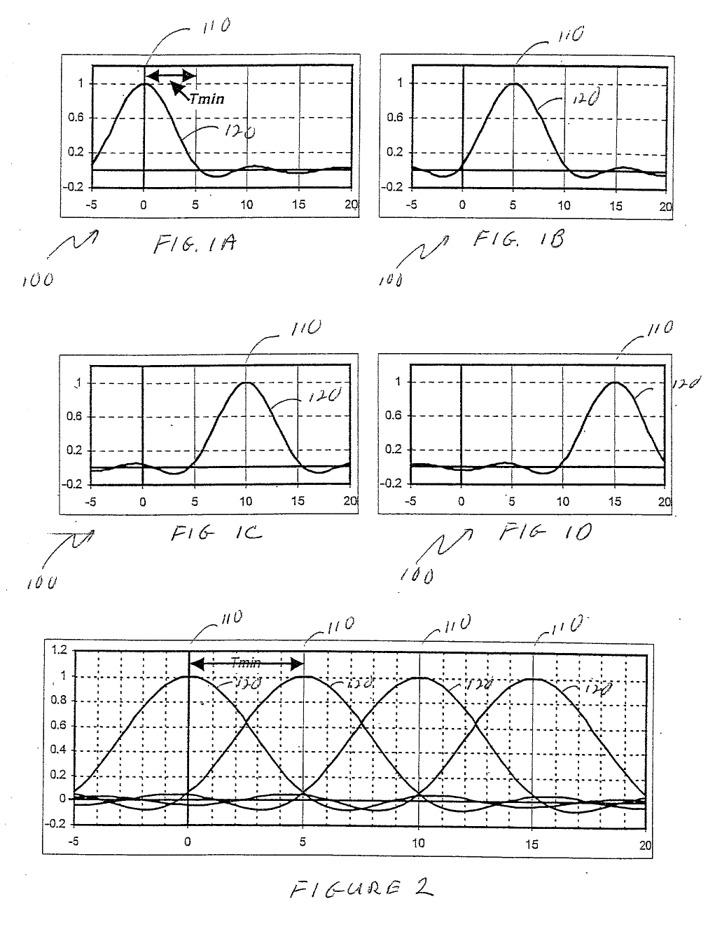

Referring initially to FIGS. 1A-1D, illustrated are graphs 100 of the pulse positions 110 of a conventional prior art digital pulse position modulation (PPM) method where data is encoded by a pulse 120 located in one of four pulse positions 110. To facilitate a better understanding of the present invention, a brief examination of PPM is helpful.

Conventional PPM provides for a stream of data to be divided into separate sample values and then using a single pulse 120 to transmit one sample value. Illustrated in FIGS. 1A-1D are the four possible values, or pulse positions 110, of a pulse 120 within a discrete span of time. The four pulse positions 110 can also be viewed as being located in a group of four slots.

By changing the position of the pulse 120 within the group of slots over a discrete span of time the data or information in the sample is transmitted. A series of pulse position 110 transmissions is used to transmit the entire stream of data. Single pulses 120 in subsequent time spans similarly transmits the information contained in subsequent sample values.

Turning now to FIG. 2, illustrated is the group of four slots separately illustrated in FIGS. 1A-1D, showing the correct conventional PPM pulse position 110 for each pulse 120. Conventional PPM provides for the transmission of only one pulse 120 in a group. When demodulation sampling is performed at each allowable peak pulse position 110 in the group, three of the samples will have a value of essentially zero and the correct sample will a value or amplitude of unity. If sampling during demodulation is not properly synchronized to these peak positions, however, then the pulse 120 amplitude at the “correct” pulse position 110 will start decreasing while the amplitude at a neighboring location will become larger than zero.

It is readily apparent that to assure a reliable transmission of data, there are a number of factors that must be considered. One of which is the minimum time interval between pulse positions 110. As a general rule, PPM requires the minimum time interval between pulse positions 110 to be sufficiently large enough to ensure that the skirt of a neighboring pulse 120 is essentially zero at the peak of an adjacent pulse 120. Also illustrated in FIG. 1A and FIG. 2 is Tmin, which is the generally recognized minimum time spacing or separation between allowable peak pulses 120 required for PPM. This Tmin is designed to improve the ability during demodulation sampling of being able to accurately identify a particular pulse 120 and separate it from the “inter-symbol” interference, if any, caused by close or adjacent pulses 120.

Another factor to consider for reliable transmission of data is the synchronization of timing of sampling to the potential pulse positions 110. If such sampling is not properly synchronized to the pulse positions 110 or if the pulse 120 is not properly within its intended slot, the amplitude for the “correct” pulse position 110 will be less than unity while the amplitude at a neighboring location will become larger than zero. Even if this were to occur, however, the signal most probably can still be correctly demodulated because PPM generally provides for only a single pulse 120 to be transmitted during the designated period of time that constitutes a group of slots. This factor generally permits the position of the pulse 120 to be correctly ascertained without much difficulty.

Timing error becomes more of a problem if significant noise exists in the system. The probability of incorrect demodulation sampling is increased when system noise is combined with substantial timing errors. On the other hand, if the timing error is small, the signal can usually be demodulated even with the presence of significant noise. As a general rule, unless the signal to noise ratio is very poor (small), the signal can be successfully demodulated as long as the timing error is less than Tmin/2.

Although PPM is widely used, the amount of data that can be encoded within a discrete time period is significantly limited. The present invention provides for a new and novel method of modulation that permits a number of pulses 120 to be included in a group of slots. This feature permits substantially more data to be encoded within a given discrete time increment and transmitted. Referring again to FIGS. 1A-1D and FIG. 2, one group of four slots permits the transmission of only 2 binary bits of data when conventional PPM techniques are employed. If four groups of four slots are used in PPM, there are 256 possible combinations of data (4 states×4 states×4 states×4 states=256 states) that can be transmitted. This corresponds to 8 bits of data, or four times more data than can be encoded in a single group. These 256 states will occupy a total of sixteen slots. If the sixteen slots are combined into a single group and conventional PPM methods are used to encode data, only one slot out of the sixteen would be occupied by a pulse 120 and 16 states would encode only 4 bits of data. This is obviously significantly less than the 256 states the same sixteen slots can accommodate when divided into four groups of four.

The benefits arising out of the utilization of multiple pulses 120 in a single group of slots are readily apparent. For example, it can be shown that if four pulses 120 are permitted to occupy any four positions in a group of sixteen slots, there are 1,820 possible states, which enables significantly more data to be encoded than the 256 states available than when using conventional PPM in four groups of four slots. Further, if eight pulses 120 can be used in the group of sixteen slots, there are 12,870 possible states available to encode data, which represents an even more significant increase in data carrying capacity. Extending the concept further and allowing 7, 8, or 9 pulses in a group of sixteen slots, there are at least 35,750 states that can be made available to encode data, which corresponds to more than 15 bits of data as compared to the 8 bits of data that can be encoded in the same space if conventional PPM is used.

A method of utilizing multiple pulses in a group of slots to encode data is described in detail in U.S. patent application Ser. No. ______, entitled MODULATION BY MULTIPLE PULSE PER GROUP KEYING AND METHOD OF USING THE SAME, Hartmann, Clinton S. (Hartmann-One), commonly assigned with the invention and incorporated herein by this reference. The invention described therein provided for multiple pulses in a group of slots, but still requires pulse positions to be separated by Tmin. The present invention provides for the use of multiple pulses in a group of slots without the more burdensome limitations found in Hartmann-One. This is done by incorporating herein certain of the principles used to encode data by simultaneous phase and time shift modulation that is described in detail in U.S. patent application Ser. No. ______, entitled MODULATION BY PHASE AND TIME SHIFT KEYING AND METHOD OF USING THE SAME, Hartmann, Clinton S. (Hartmann-Two), commonly assigned with the invention and incorporated herein by this reference.

The ability to successfully distinguish between two possible positions of a single pulse is critical when multiple pulses are being used in a group of slots. When the pulses are partially overlapped (as illustrated by the waveforms in FIG. 2), so that the skirt of one allowable pulse position overlaps an adjacent pulse position it becomes more difficult to demodulate the signal so that the pulse position originally encoded can be detected. As the overlap becomes larger, detection becomes even more problematic.

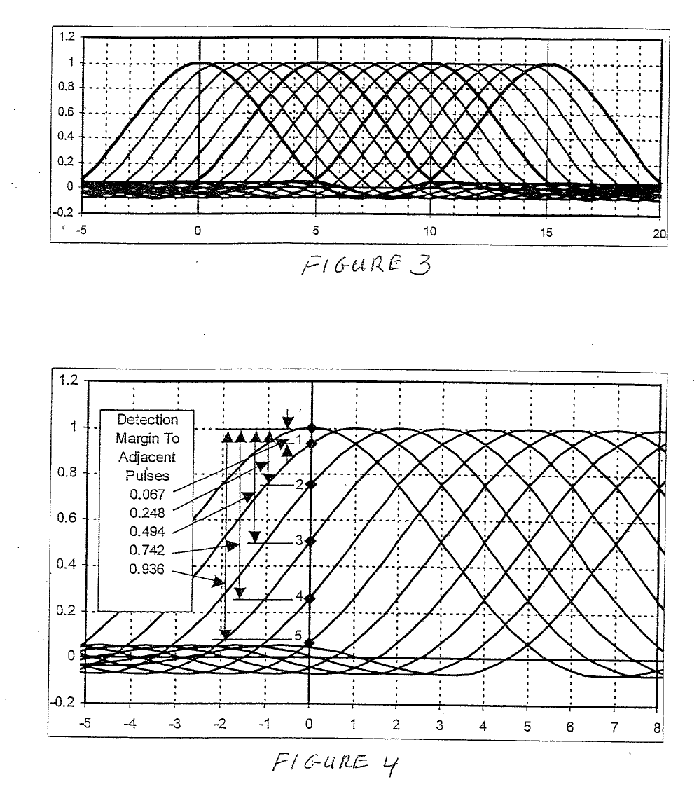

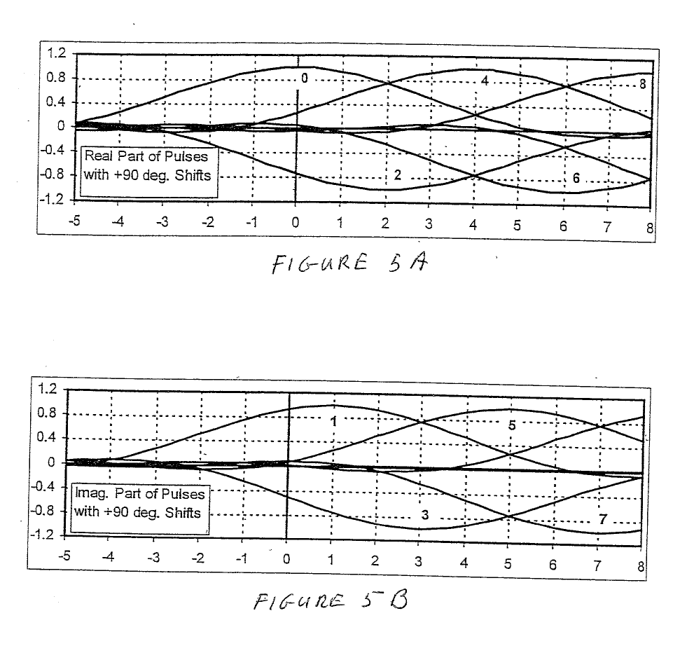

Turning now to FIG. 3, illustrated is an example of waveforms of multiple pulses with a large skirt overlap between adjacent pulse positions. Because of the significant skirt overlap, it is readily apparent that discrimination will be particularly poor with respect to an adjacent pulse position. While increasing the number of pulses in a group of slots increases data density, it is a method rarely used in PPM because of the obvious reduction in detection margin.

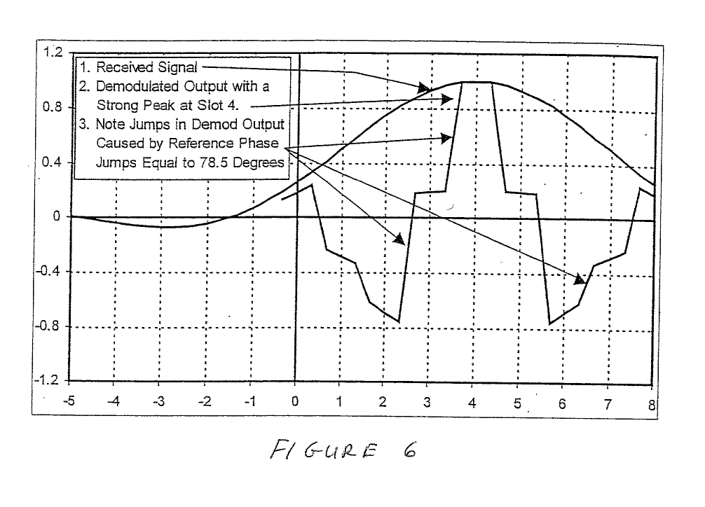

Turning to FIG. 4, illustrated is a graph showing the limited detection margin between adjacent slot positions where a signal has strongly overlapping pulses. To demodulate a signal with such strongly overlapping pulses excellent synchronization is needed, which means that it is critical for the received signal to be sampled at the peak locations of all possible pulse positions (i.e. at all integer locations on the horizontal axis). The signal to noise ration must also be very strong (i.e., even small noise amounts can be larger than the small detection margin).

To enable more efficient and positive discrimination between pulses, the present invention provides for allowable pulses to be modified such that each pulse, not only has a different time position, but also has a different phase from its adjacent pulse. For example, if a phase step of ±90 degrees is added between each adjacent pulse, then the pulse at t=0 (time equals zero) might have 0° phase angle, the pulse at t=1 will have ±90°, the pulse at t=2 will have ±180°, the pulse at t=3 will have ±270°, the pulse at t=4 will have ±360°, etc.

Turning now to FIGS. 5A-5B, illustrated are the real and imaginary parts of allowable pulses for the case of +90° phase being added between each adjacent pulse. Using multiples of 90°, as illustrated, all odd numbered pulses have real parts equal to zero and all even numbered pulses have imaginary parts equal to zero. As will be apparent to one of ordinary skill in the pertinent art, however, it can be shown that, in general, a wide range of angles can be used, many of which give equal or better performance than the illustrated 90° case. For example, the phase angle differential could be varied by more than ±20° without significant degradation of the ability to detect pulses during demodulation.

To demodulate the illustrated signal, the real part of the received signal would be sampled at the appropriate peak locations (t=0, 1, 2, etc.). In addition, the phase of the sampling signal would also be shifted from one slot to the next, so that the sampling signal would agree with the expected phase of a pulse at that slot location if a pulse should occur at such location.

Turning now to FIG. 6, illustrated is a graph showing the wave forms for an embodiment of the present invention using a 78.5° phase difference between adjacent allowed states. A phase increment other than 90° is shown to demonstrate the substantially improved discrimination that exists between a correct state and its neighboring states for allowable pulse spacings of Tmin/5 as compared to the identical allowed pulse spacing without phase shifts that was illustrated in FIG. 3. This graph also illustrates the substantially improved discrimination that exists between a correct state and its neighboring states for a phase angle shift other than 90°. As can be seen there is a dramatic improvement in discrimination when compared to the more conventional PPM with allowable pulse spacing of Tmin and no phase shift. Without the phase shifts, the detection minimum margin is 0.067 while, with the phase shifts, the detection margin to adjacent states is now 0.81, which is close to a conventional PPM detection margin approaching unity.

Thus the present invention is best characterized as using multiple pulses in a group of slots and simultaneously shifting both the phase and the time location of a pulse signal for adjacent pulse positions in a known manner. By mapping the encoding, the amount of data that can be sent and decoded is substantial. Mapping constitutes a predetermined arrangement whereby an encoded signal has a specific meaning attributable to such signal that can be ascertained when such signal is decoded or demodulated. This agreement can take the form of a protocol, such as an agreed upon table of codes, or other arrangement whereby an encoded signal has a reliable and ascertainable meaning when decoded. The advantage of using the present invention to encode a data message is clear. A vast amount of information to be encoded on data elements within a propagated signal to permit the transfer of substantial data over a very short period of time, thus conserving bandwidth. In one embodiment of the invention, for example, more than fifteen bits of data can be encoded in a single group and, by mapping the codes used, reliably decoded.

In Hartmann-One a new method of modulation was described using multiple pulses in a group. In Hartmann-Two a new type of modulation was described providing for a simultaneous phase and time shift between pulse positions which permitted allowable pulse positions to have a significantly smaller time interval. The present invention uses both of these features with the addition of certain other features that permit the two methods to be simultaneously employed.

In the multiple pulse per group of slots situation of Hartmann-One, two adjacent slots were permitted to be occupied because, as illustrated in FIG. 3, the skirt of one pulse did not overlap the peak of its neighboring pulse. However, if two adjacent or closely neighboring slots are to be simultaneously occupied using strongly overlapping pulses, the potential for strong inter-symbol interference exists between pulses that could result in almost total cancellation between the two, if a significant enough phase shift between pulses was present or a significant synchronization demodulation error existed. This potential interference needs to be addressed.

One method of solving the foregoing potential interference problem is to impose a minimum pulse spacing rule when combining multiple pulses per group modulation with simultaneous phase and time shift modulation. An example of a generally useful rule is that, while the allowable pulse positions can have time separations that are significantly smaller than Tmin, in a specific phase of a waveform any two pulses included in that waveform phase must always have a minimum spacing greater than Tmin.

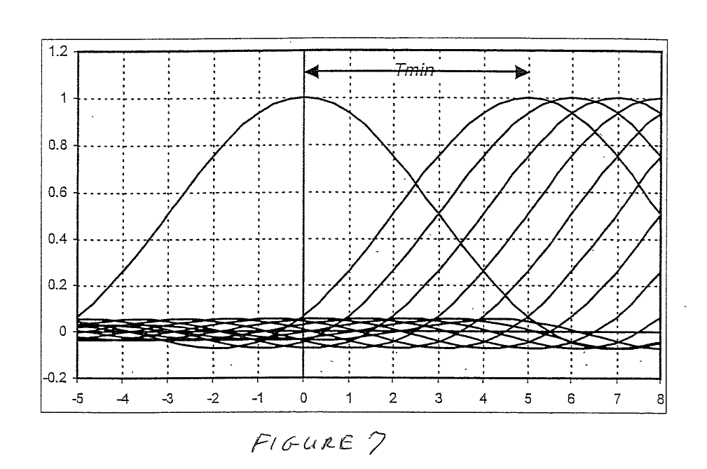

Turning to FIG. 7, illustrated is an example of an application of a minimum spacing rule that allows multiple pulses per group along with simultaneous phase and time shift modulation. In this example, one pulse in the selected phase of a waveform occurs at t=0. In accordance with the above described minimum pulse spacing rule, the next pulse in that particular phase of the waveform is excluded from positions t=1, 2, 3, and 4, but is allowed to occur at any position after t=5. In this example, for the waveform shown, at least four pulse slots had to be skipped between selected pulses where Tmin is equal to five slots. A general rule can be constructed such that if a slot width equals Tmin/N then a skip factor can be defined as N−1. Obviously, larger skip factors can be used and be well within the scope of the present invention as well as being beneficial, such as, for example, in operating environments with strong outside interference. Of course, somewhat smaller skip factors may also be beneficial in certain other cases.

Another method for solving potential interference problems between two adjacent slots when multiple pulses are being used in a group together with time and phase shift modulation is based on the orthogonality between adjacent slots where a phase shift between slots is ±90 degrees. If the phase shift is sufficiently close to ±90 degrees, then a pulse in any given slot will not interfere with either of the two adjacent slots. In this case, all odd numbered slots become totally independent of all even numbered slots. However, as pointed out above, a pulse can still interfere with its neighbors where the same pulse phase exists, if the spacing of these neighbors is closer than Tmin. In this special “orthogonal nearest neighbor” case, a useful method for analyzing the options is to divide the slots into two intertwined sub-groups, such as an I group and a Q group. Then, if necessary, the Tmin minimum spacing rule illustrated herein can be separately applied to each such sub-group. The new type of modulation described herein, characterized by using multiple pulses per group combined with simultaneous phase and time shift between slots, generally allows for a significant overlap between pulses in neighboring slots.

While the embodiment of the invention described herein provides for uniformly spaced time shifts and uniformly spaced phase shifts, those of ordinary skill in the pertinent art will understand that non-uniform spacing of time shifts or phase shifts (or both) is well within the intended scope of the present invention. Similarly, groups can vary in the number of slots and/or in the number of occupied slots and still be within the scope of the present invention. Also, a single group can be defined such that it only has a fixed number of occupied slots or, alternatively, it might allow for a varying number of occupied slots. Also, a single data message could include more than one type of group (for example the header might be one type of group, the actual data a second type of group, an error detection/correction word might be of a third type, and synchronization might be a fourth). As will be recognized by those of ordinary skill in the pertinent art, all of these variants as well as others are well within the intended scope of the present invention.

The present invention also provides several embodiments of methods for propagating a signal. In one such embodiment the method calls for designating a time period divided into a group of time slots each having a unique phase/time position. The method then provides for distributing multiple pulses among such time slots to encode a data element by a unique phase/time position. The invention includes several other embodiments of methods for propagating a signal. Sufficient detail has been set forth herein to enable one of ordinary skill in the pertinent art to understand and practice the various embodiments of such methods.

Although the present invention has been described in detail, those skilled in the art should understand that they can make various changes, substitutions and alterations herein without departing from the spirit and scope of the invention in its broadest form.

What is claimed is:

1. A propagated signal, comprising:
a time period divided into a group of time slots each having a unique phase/time position; and
multiple pulses distributed among said time slots encoding a data element by said unique phase/time position.

2. The propagated signal as recited in claim 1 wherein said data element is ascertainable by mapping.

3. The propagated signal as recited in claim 1 wherein said time slots in said group are adjacent.

4. The propagated signal as recited in claim 1 wherein said time slots in said group are not adjacent.

5. The propagated signal as recited in claim 1 wherein said time slots have a non-uniform spacing.

6. The propagated signal as recited in claim 1 wherein said data element is at least fifteen bits long.

7. The propagated signal as recited in claim 1 wherein said data element is selected from the group consisting of:
a header;
an error detection message;
a synchronization element; and
a data message.

8. The propagated signal as recited in claim 1 further comprising a plurality of said time periods.

9. The propagated signal as recited in claim 8 wherein said groups have differing numbers of multiple pulses.

10. The propagated signal as recited in claim 8 wherein said number of time slots vary in said time periods.

11. A method of propagated a signal, comprising:
designating a time period divided into a group of time slots each having a unique phase/time position; and
distributing multiple pulses among said time slots to encode a data element by said unique phase/time position.

12. The method as recited in claim 11 wherein said data element is ascertainable by mapping.

13. The method as recited in claim 11 wherein said time slots in said group are adjacent.

14. The method as recited in claim 11 wherein said time slots in said group are not adjacent.

15. The method as recited in claim 11 wherein said time slots have a non-uniform spacing.

16. The method as recited in claim 11 wherein said data element is at least fifteen bits long.

17. The method as recited in claim 11 wherein said data element is selected from the group consisting of:
a header;
an error detection message;
a synchronization element; and
a data message.

18. The method as recited in claim 11 further comprising a plurality of said time periods.

19. The method as recited in claim 18 wherein said groups have differing numbers of multiple pulses.

20. The method as recited in claim 18 wherein said number of time slots vary in said time periods.
